(19) United States
(12) Patent Application Publication
(10) Pub. No.: US 2007/0000649 A1
(43) Pub. Date: Jan. 4, 2007

(54) Auxiliary heat-dissipating device

(75) Inventor: Cheng-Kuo Peng, Keelung (TW)

Correspondence Address: BACON & THOMAS, PLLC, 625 SLATERS LANE, FOURTH FLOOR, ALEXANDRIA, VA, 22314, US

(73) Assignee: TUL CORPORATION, Taipei (TW)

(21) Appl. No.: 11/429,162

(22) Filed: May 8, 2006

(30) Foreign Application Priority Data
Jul. 4, 2005 (TW) 94122524

(51) Int. Cl. H01L 23/467

(52) U.S. Cl. 165/121

(57) ABSTRACT

An auxiliary heat-dissipating device is provided, comprising: an expansion back plate having a plurality of vents and forming a respective slide on two vertical sides; a first shell positioned on the slide of the expansion back plate, the first shell has a first end opening and a second end opening, and the first end opening is aligned with the vents of the expansion back plate; a second shell having a first end opening and a second end opening, and the first end opening of the second shell will be inserted by the second end opening of the first shell; and a fan module provided within the first shell, the fan module will drive the wind flow between the vents of the expansion back plate and the second end opening of the second shell.

### BACKGROUND OF THE INVENTION

1. Field of the Invention

The present invention relates to an auxiliary heat-dissipating device, and more particularly to an auxiliary heat-dissipating device being able to adjust the position of vents in the first direction and the second direction, and method thereof.

2. Description of the Related Art

Recently, as the vigorous development of the electronic industry, various electronic products have made people's life more comfortable. When the operating speed is increasing, the temperature of the electronic element (such as CPU, hard disk, displaying card, . . . etc.) is thus easily getting higher. Accordingly, the heat-dissipating fan has become a very popular heat-dissipater and is widely used. However, the heat-dissipating problems of them are always annoying the user. In general, high temperature of an electronic element in operation will adversely influence its operation efficiency and lifetime. Because most users often operate a computer for a long time and sometimes do not shut it off after the end of the operation, much heat will often be accumulated in the inside of the computer housing. When these heat amounts are left in the inside of the housing, the electronic elements (such as CPU, hard disk, displaying card, chipset, . . . etc.) on the motherboard will achieve a very high temperature, causing the computer to be shut down or even to be burn down. Therefore, the heat-dissipating issue is very important for related computer products.

Some current commercially available heat-dissipating fan modules are designed for the fixed size of a specific element (such as the CPU of a computer), thus the heat-dissipating fan only can perform the heat-dissipating function for the CPU of a computer and can not apply to other electronic elements. Therefore, the practicability is not high.

Further, these heat-dissipating fans are only for lowering the temperature inside the computer housing and do not have the function of dissipating the heat of electronic elements, and the expansion ability is limited. Thus, conventional heat-dissipating fans still have disadvantages and need to be improved.

### SUMMARY OF THE INVENTION

It is one object of the present invention to provide an auxiliary heat-dissipating device to achieve better heat-dissipating effect by using a fan module to introduce the cool air from the outside of a housing to the inside of the housing (or to introduce the hot air from the inside of a housing to the outside of the housing), even to directly introduce the cool air onto the element whose heat need to be dissipated.

It is another object of the present invention to provide an auxiliary heat-dissipating method for dissipating the heat of a heating portion of an expansion card.

For achieving the abovementioned purposes, an auxiliary heat-dissipating device comprises an expansion back plate having a plurality of vents and forming a respective slide on two vertical sides; a first shell positioned on the slide of the expansion back plate, the first shell has a first end opening and a second end opening, and the first end opening is aligned with the vents of the expansion back plate; a second shell having a first end opening and a second end opening, and the first end opening of the second shell will connect the second end opening of the first shell; and a fan module provided within the first shell, the fan module will drive the wind flow between the vents of the expansion back plate and the second end opening of the second shell.

Preferably, the first shell can be moved with respect to the expansion back plate in the first direction and is positioned on the slide.

Preferably, the first direction is parallel to the vertical direction of the expansion back plate.

Preferably, the second shell can be moved with respect to the expansion back plate in the second direction and is positioned on the first shell.

Preferably, the second direction is perpendicular to the vertical direction of the expansion back plate.

Preferably, the flowing-out direction of the fan module is aligned with the second end opening of the first shell.

For achieving the abovementioned purposes, an auxiliary heat-dissipating method comprises: providing a plurality of vents on an expansion back plate; adjusting the first shell to be moved with respect to the expansion back plate in the first direction and to position the first shell on the expansion back plate; coupling the second shell to the first shell to form a channel; adjusting the second shell to be moved with respect to the expansion back plate in the second direction and to position the second shell on the first shell; providing a fan module installed within the first shell; and adjusting the end opening of the channel in the first direction and the second direction to be aligned with the heating portion.

Preferably, the method further comprises: extending a pair of slides on two vertical sides of the expansion back plate, using a pair of locking units to fix the first shell on the slide.

Preferably, the first direction is parallel to the vertical direction of the expansion back plate.

Preferably, the second direction is perpendicular to the vertical direction of the expansion back plate.

Preferably, the expansion card is a video graphic adapter card, a TV card, or a motherboard.

Preferably, the heating portion is the processor/integrated circuit of the expansion card.

### BRIEF DESCRIPTION OF THE DRAWINGS

FIG. 1 is an exploded three-dimensional view of an auxiliary heat-dissipating device according the first embodiment of the present invention.

FIG. 2 is an assembly three-dimensional view of the auxiliary heat-dissipating device according the first embodiment of the present invention.

FIG. 3 is an exploded three-dimensional view of an auxiliary heat-dissipating device according the second embodiment of the present invention.

FIG. 4 is an assembly three-dimensional view of the auxiliary heat-dissipating device according the second embodiment of the present invention.

FIG. 5A is a front view of the auxiliary heat-dissipating device according the second embodiment of the present invention, and FIG. 5B is a top view of the auxiliary heat-dissipating device according the second embodiment of the present invention in conjunction with an expansion card.

FIG. 6 is a top view of the auxiliary heat-dissipating device according the third embodiment of the present invention in conjunction with an expansion card.

FIG. 7 is a front view of the auxiliary heat-dissipating device according the first embodiment of the present invention.

### DETAILED DESCRIPTION OF THE PREFERRED EMBODIMENTS

Although the present invention will be sufficiently described with reference to accompany figures containing preferred embodiments thereof, it should be understood before the description that those skilled in the art can easily make changes to the present invention described herein and obtains the same performance as that of the present invention. Therefore, it is to be understood that both the following description is a general disclosure to those skilled in the art only and is not restrictive of the invention.

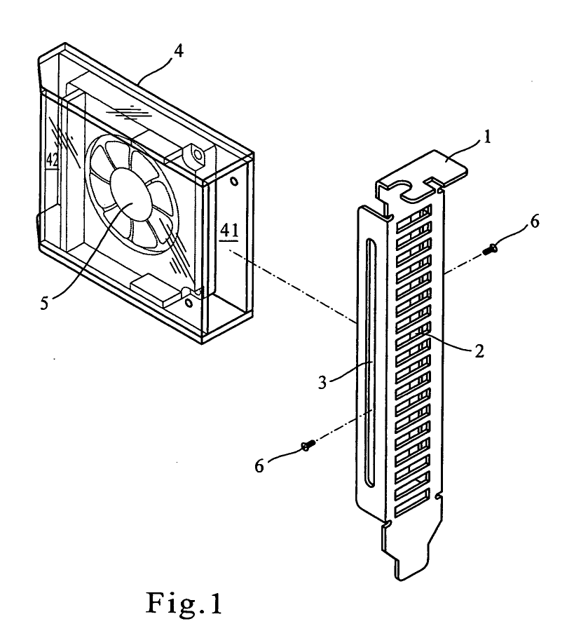

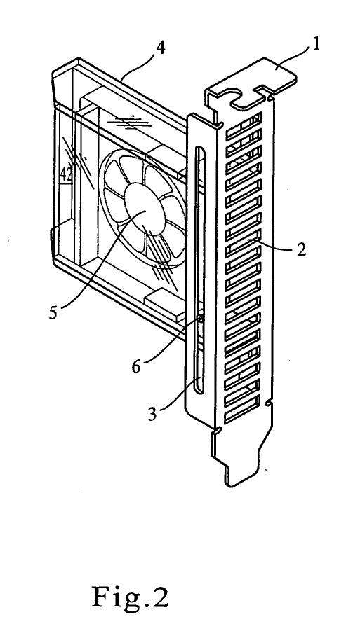

Referring to FIG. 1 and FIG. 2, an exploded three-dimensional view and an assembly three-dimensional view of an auxiliary heat-dissipating device according the first embodiment of the present invention are respectively shown. In this preferred embodiment, an auxiliary heat-dissipating device of the present invention contains an expansion back plate 1 having a plurality of vents 2 and forming a respective slide 3 on two vertical sides; a first shell 4 positioned on the slide 3 of the expansion back plate 1, the first shell 4 has a first end opening 41 and a second end opening 42, and the first end opening 41 is aligned with the vents 2 of the expansion back plate 1; and a fan module 5 provided within the first shell 4, the fan module 5 will drive the wind flow between the vents 2 of the expansion back plate 1 and the second end opening 42 of the first shell 4.

The first shell 4 is positioned on the slide 3 of the expansion back plate 1 via a screw 6, and will form the auxiliary heat-dissipating device of the present invention by combining with the fan module 5.

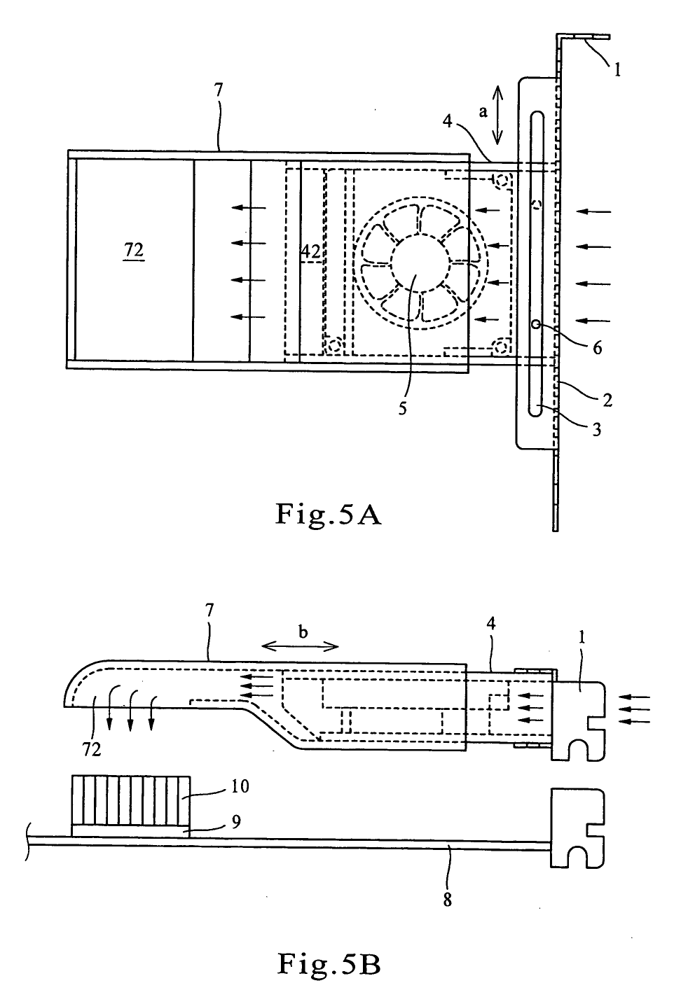

When the first shell 4 is positioned on the slide 3, the first shell 4 will be moved with respect to the expansion back plate 1 in the first direction. Referring to FIG. 5A, the first direction is the vertical direction parallel to the expansion back plate 1 as shown by the direction indicated by arrow a in this figure.

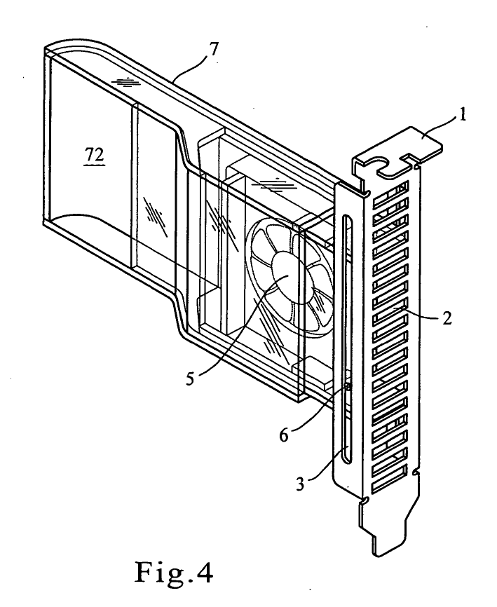

Referring to Fig, 3 and FIG. 4, an exploded three-dimensional view and an assembly three-dimensional view of an auxiliary heat-dissipating device according the second embodiment of the present invention are respectively shown. In this preferred embodiment, an auxiliary heat-dissipating device of the present invention contains an expansion back plate 1 having a plurality of vents 2 and forming a respective slide 3 on two vertical sides; a first shell 4 positioned on the slide 3 of the expansion back plate 1, the first shell 4 has a first end opening 41 and a second end opening 42, and the first end opening 41 is aligned with the vents 2 of the expansion back plate 1; a second shell 7 having a first end opening 71 and a second end opening 72; and a fan module 5 provided within the first shell 4, the fan module 5 will drive the wind flow between the vents 2 of the expansion back plate 1 and the second end opening 72 of the second shell 7.

The first shell 4 is positioned on the slide 3 of the expansion back plate 1 via a screw 6, the first end opening 71 of the second shell 7 will be inserted by the second end opening 42 of the first shell 4 and will form the auxiliary heat-dissipating device of the present invention by combining with the fan module 5.

When the first shell 4 is positioned on the slide 3, the first shell 4 will be moved with respect to the expansion back plate 1 in the first direction. When the first end opening 71 of the second shell 7 is inserted by the second end opening 42 of the first shell 4, the second shell 7 will be moved with respect to the expansion back plate 1 in the second direction. Referring to FIG. 5B, the second direction is the vertical direction perpendicular to the expansion back plate 1 as shown by the direction indicated by arrow b in this figure.

Referring to FIG. 5A, a front view of the auxiliary heat-dissipating device according the second embodiment of the present invention is shown. When the fan module 5 is operated to drive the wind flow, then the wind will pass through in the exterior of the expansion back plate 1 sequentially the vents 2, the first end opening 41, the fan module 5, the second end opening 42 in the direction indicated by the bold arrow in the figure, and finally flows out through the second end opening 72 of the second shell 7.

Referring to FIG. 5B, a top view of the auxiliary heat-dissipating device according the second embodiment of the present invention in conjunction with an expansion card is shown. When the auxiliary heat-dissipating device and an expansion card 8 (which may be a video graphic adapter card or a TV card or a motherboard) adjoining the auxiliary heat-dissipating device are provided in a computer housing (not shown) and operated, then the processor/integrated circuit 9 of the expansion card 8 will generate heat, and the heat sink 10 provided on the processor/integrated circuit 9 is used to help dissipate the heat generated by the processor/integrated circuit 9. Because the first shell 4 is moved with respect to the expansion back plate 1 in the first direction and the second shell 7 is moved with respect to the expansion back plate 1 in the second direction, allowing that the second end opening 72 of the second shell 7 can be adjusted with respect to the position of the processor/integrated circuit 9 of the expansion card 8, thereby when the second end opening 72 of the second shell 7 is aligned with the heat sink 10 provided on the processor/integrated circuit 9 and the fan module 5 is activated (referring to FIG. 5A) to drive the wind flow in the direction indicated by the bold arrow in the FIG. 5B, the wind flow of the second end opening 72 thus can effectively decrease the temperature of the processor/integrated circuit 9 to assure the work performance thereof.

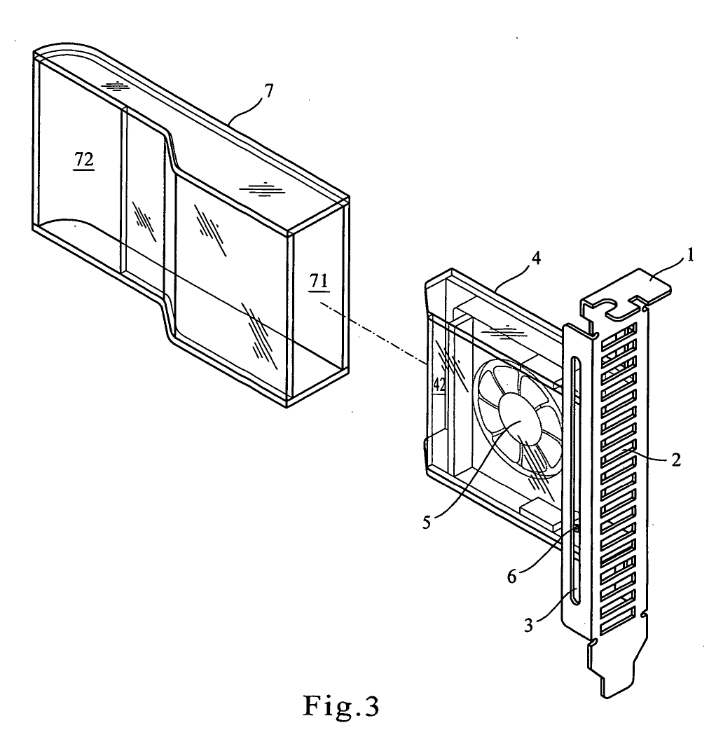

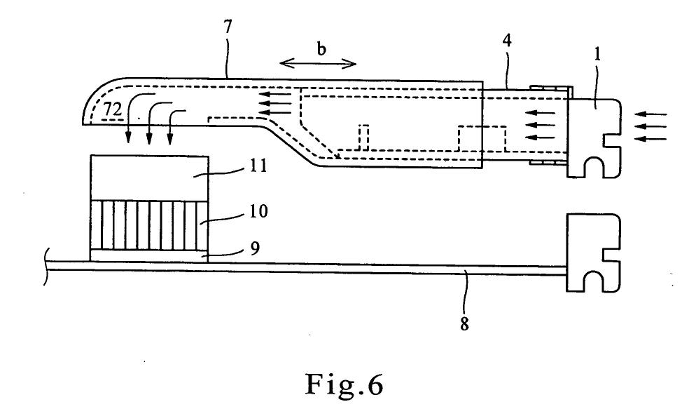

Referring to FIG. 6 in conjunction with FIG. 3 and FIG. 4, a top view of the auxiliary heat-dissipating device according the third embodiment of the present invention in conjunction with an expansion card is shown, wherein the processor/integrated circuit 9 of the expansion card 8 utilizes a fan module 11 and the heat sink 10. In this preferred embodiment, an auxiliary heat-dissipating device of the present invention contains an expansion back plate 1 having a plurality of vents 2 and forming a respective slide 3 on two vertical sides; a first shell 4 positioned on the slide 3 of the expansion back plate 1, the first shell 4 has a first end opening 41 and a second end opening 42, and the first end opening 41 is aligned with the vents 2 of the expansion back plate 1; and a second shell 7 having a first end opening 71 and a second end opening 72.

When the first shell 4 is positioned on the slide 3, the first shell 4 will be moved with respect to the expansion back plate 1 in the first direction. When the first end opening 71 of the second shell 7 is inserted by the second end opening 42 of the first shell 4, the second shell 7 will be moved with respect to the expansion back plate 1 in the second direction.

The heat generated by the processor/integrated circuit 9 is first transferred to the heat sink 10, when the fan module 11 is activated to drive the wind flow in the direction indicated by a bold arrow in this figure, then the wind will pass through in the exterior of the expansion back plate 1 sequentially the vents 2, the first shell 4, and the second shell 7, and finally flows out through the second end opening 72 of the second shell 7, and the fan module 11 will dissipate the heat of the heat sink 10, thereby effectively decreasing the temperature of the processor/integrated circuit 9 to assure the work performance thereof.

Further, the user may select the type of the fan module 11. Whether the fan module 11 is an exhaust fan module, an air-blowing fan module, or an exhaust and air-blowing combined fan module, the purpose of decreasing the temperature of the processor/integrated circuit 9 can be achieved to assure the work performance thereof.

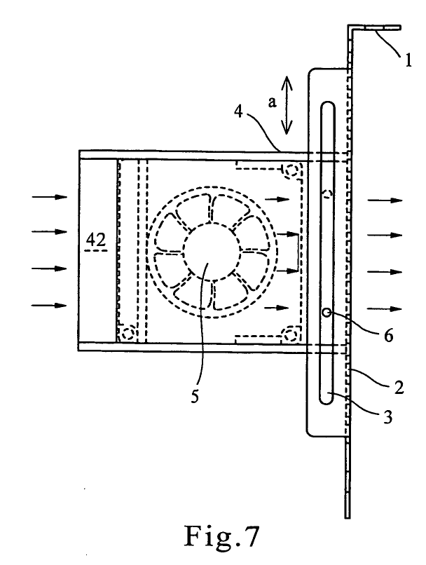

Referring to FIG. 7, a front view of the auxiliary heat-dissipating device according the first embodiment of the present invention is shown, wherein the fan module 5 is selected to be an exhaust type fan module 5. When the fan module 5 is activated to drive the wind flow in the direction indicated by the bold arrow in FIG. 7, the heat (or hot wind) generated in the computer housing (not shown) will be introduced to the exterior of the expansion back plate 1 sequentially through the second end opening 42, the first shell 4, and the vents 2, thereby effectively decreasing the temperature inside the computer housing to assure the work performance of the expansion card configured within the computer housing. After describing preferred embodiments of the present invention in detail, it will be clearly recognized to those skilled in the art that various changes and modifications may be made without departing from the range and spirit of the following claims, and the invention is not limited to the implementations of these embodiments cited in the above specification. For example, according to an alternative embodiment of the present invention, an auxiliary heat-dissipating device may comprise an expansion back plate having vents; a shell having a first end opening and a second end opening; a positioning device for sliding in the first direction and positioning the first end opening of the shell to be aligned with the vents of the expansion back plate, and the shell has an extension portion for extending to position the second end opening in the second direction (i.e. the vertical direction perpendicular to the expansion back plate); and a fan module provided within the shell, the fan module will drive the wind flow between the vents of the expansion back plate and the second end opening. Wherein the positioning device includes a pair of slides extending from the two vertical sides of the expansion back plate, the slides will define the first direction (i.e. the vertical direction parallel to the expansion back plate); a pair of locking units for positioning the shell on the slides.

What is claimed is:

1. An auxiliary heat-dissipating device, comprising:
an expansion back plate having a plurality of vents;
a first shell having a first end opening and a second end opening, and a fan module is provided within inside; and
a positioning device for defining the sliding movement of said first shell with respect to said expansion back plate, and positioning the first end opening of said first shell to be aligned with the vents of said expansion back plate.

2. The auxiliary heat-dissipating device according to claim 1, further comprising a second shell having a first end opening and a second end opening, the first end opening of said second shell connects the second end opening of said first shell.

3. The auxiliary heat-dissipating device according to claim 2, wherein said fan module drives the wind flow between the vents of said expansion back plate and the second end opening of said second shell.

4. The auxiliary heat-dissipating device according to claim 2, wherein said second shell can be moved with respect to said expansion back plate in the second direction and is positioned on said first shell.

5. The auxiliary heat-dissipating device according to claim 4, wherein said second direction is the vertical direction perpendicular to said expansion back plate.

6. The auxiliary heat-dissipating device according to claim 1, wherein said first shell can be moved with respect to said expansion back plate in the first direction and is positioned by said positioning device.

7. The auxiliary heat-dissipating device according to claim 6, wherein said first direction is the vertical direction parallel to said expansion back plate.

8. The auxiliary heat-dissipating device according to claim 1, wherein the flowing-out direction of said fan module is aligned with the second end opening of said first shell.

9. An auxiliary heat-dissipating device, comprising:
an expansion back plate having a plurality of vents and forming a respective slide on two vertical sides;
a first shell positioned on the slides of the expansion back plate, said first shell defines a first channel, and said first channel is aligned with the vents of said expansion back plate; and
a second shell for defining a second channel, said second shell is slidably coupled to said first shell to connect the second channel and the first channel.

10. The auxiliary heat-dissipating device according to claim 9, further comprising a fan module provided with said first shell, said fan module drives the wind flow between the vents of said expansion back plate and the second end opening of said second shell.

11. An auxiliary heat-dissipating device, comprising:
an expansion back plate having vents;
a shell having a first end opening and a second end opening; and
a positioning device for sliding in the first direction and positioning the first end opening of said shell to be aligned with the vents of said expansion back plate.

12. The auxiliary heat-dissipating device according to claim 11, wherein said shell has an extension portion for extending to position the second end opening in the second direction.

13. The auxiliary heat-dissipating device according to claim 11, wherein said positioning device includes a pair of slides extending from the two vertical sides of said expansion back plate, the slides defines the first direction; a pair of locking units for positioning said shell on said slides.

14. The auxiliary heat-dissipating device according to claim 11, further comprising a fan module provided with said shell, said fan module drives the wind flow between the vents of said expansion back plate and said second end opening.
